(19) United States
(12) Patent Application Publication
(10) Pub. No.: US 2023/0323525 A1
(43) Pub. Date: Oct. 12, 2023

(54) SUBSTRATE PROCESSING APPARATUS AND COVER RING ASSEMBLY

(71) Applicant: LAPIS Semiconductor Co., Ltd., Yokohama (JP)

(72) Inventors: Masashi TAKAHASHI, Yokohama (JP); Atsushi CHIBA, Yokohama (JP)

(73) Assignee: LAPIS Semiconductor Co., Ltd., Yokohama (JP)

(21) Appl. No.: 18/189,356

(22) Filed: Mar. 24, 2023

(30) Foreign Application Priority Data
Mar. 29, 2022 (JP) 2022-53798

(51) Int. Cl. C23C 14/34; H01J 37/34; C23C 4/06; C23C 14/50; H01J 37/32

(52) U.S. Cl. CPC C23C 14/34; C23C 4/06; C23C 14/50; H01J 37/32477; H01J 37/32642; H01J 37/3488

(57) ABSTRACT

Provided is a cover ring assembly that allows suppressing a dust generation source and reducing adhesion of particles on a substrate. A cover ring assembly for a substrate processing apparatus, which exposes a substrate to processing particles in an internal space to process the substrate, includes an annular flat plate and a cover ring having an annular shape. The annular flat plate has an inner peripheral upper surface and an outer peripheral upper surface. The inner peripheral upper surface is in contact with an outer peripheral lower surface terminating at an outer surface of the substrate. The outer peripheral upper surface is around the inner peripheral upper surface. The cover ring has a lower portion surface having an abutting surface in contact with the outer peripheral upper surface of the annular flat plate. A thermal spraying film covering a surface exposed to the processing particles is disposed to the cover ring except for the abutting surface.

### CROSS-REFERENCE TO RELATED APPLICATION

This application is based upon and claims the benefit of priority from the prior Japanese Patent Application No. 2022-053798 filed on Mar. 29, 2022, the entire contents of which are incorporated herein by reference.

### BACKGROUND OF THE INVENTION

### 1. Technical Field

The present invention relates to a substrate processing apparatus and a cover ring assembly of a sputtering apparatus or the like.

### 2. Description of the Related Art

For example, JP-A-9-176848 discloses a typical configuration of an apparatus inside a chamber of a sputtering apparatus. WO 2014/103168 discloses a method for forming a thermal spraying film on a cover ring or the like of a sputtering apparatus.

As indicated in WO 2014/103168, in a sputtering apparatus, an aluminum thermal spraying film is formed on a cover ring and a pedestal ring part so as to suppress film delamination of a metal sputtering film. However, in an area of a structure like a cover ring and a pedestal ring where contact is repeated, there has been a problem that particles have been generated by thermal spraying films rubbing against one another.

The present invention is made in consideration of the above-mentioned problem of the related art, and it is one example of an object of the present invention to provide a substrate processing apparatus and a cover ring assembly that allow reducing adhesion of particles on a substrate.

### SUMMARY OF THE INVENTION

A substrate holding assembly according to the present invention includes an annular flat plate and a cover ring. The annular flat plate is removably mounted to an outer peripheral portion on an upper surface of a substrate support having a disc shape. The substrate support is housed in an internal space formed by a processing chamber of a substrate processing apparatus. The substrate support is movable in a vertical direction, the upper surface holding a substrate. The cover ring has a lower surface with an inner edge portion. The cover ring has an annular abutting surface on the inner edge portion. The annular abutting surface abuts on the annular flat plate when the substrate support moves upward in the vertical direction. Thermal spraying films are formed on surfaces of the annular flat plate and the cover ring, and the abutting surfaces of the annular flat plate and the cover ring against one another are exposed from the thermal spraying films.

A substrate processing apparatus according to the present invention includes a processing chamber, a substrate support, and a cover ring. The substrate support is disposed in the processing chamber and is movable in a vertical direction. The substrate support has an upper surface with a substrate holding surface. The substrate holding surface has a substrate holding area and an annular area. The substrate holding area is configured to contact and hold a substrate. The annular area is disposed in an annular shape in a peripheral edge of the substrate holding area. The cover ring has an annular shape and a lower surface with an inner edge portion. The cover ring has an annular abutting surface at the inner edge portion of the lower surface. The cover ring is disposed in the processing chamber. The annular abutting surface abuts on the annular area when the substrate support moves upward in the vertical direction. Thermal spraying films are formed on surfaces of the substrate holding surface and the cover ring, and the abutting surfaces of the substrate support and the cover ring against one another are exposed from the thermal spraying films.

A substrate holding assembly according to the present invention includes a substrate support and a cover ring. The substrate support is housed in an internal space formed by a processing chamber of a substrate processing apparatus and is movable in a vertical direction. The substrate support has an upper surface with a substrate holding surface. The substrate holding surface has a substrate holding area and an annular area. The substrate holding area is configured to contact and hold a substrate. The annular area is disposed in an annular shape of a peripheral edge of the substrate holding area. The cover ring has an annular shape and a lower surface with an inner edge portion. The cover ring has an annular abutting surface at the inner edge portion of the lower surface. The annular abutting surface abuts on the annular area when the substrate support moves upward in the vertical direction. Thermal spraying films are formed on surfaces of the substrate holding surface and the cover ring, and the abutting surfaces of the substrate support and the cover ring against one another are exposed from the thermal spraying films.

A cover ring assembly according to the present invention is for a substrate processing apparatus that exposes a substrate to processing particles in an internal space to process the substrate. The cover ring assembly includes an annular flat plate, a cover ring, and a thermal spraying film. The annular flat plate has an inner peripheral upper surface and an outer peripheral upper surface. The inner peripheral upper surface is in contact with an outer peripheral lower surface terminating at an outer surface of the substrate. The outer peripheral upper surface is around the inner peripheral upper surface. The cover ring has an annular shape and a lower portion surface. The lower portion surface having an abutting surface being in contact with the outer peripheral upper surface of the annular flat plate. The thermal spraying film covers a surface exposed to the processing particles is disposed to the cover ring except for the abutting surface.

According to the substrate holding assembly, the substrate processing apparatus, and the cover ring assembly of the present invention, since the thermal spraying film is not formed in the area where the cover ring is in contact with a pedestal ring (the annular flat plate), it is possible to obtain an effect that a dust generation source can be suppressed to reduce adhesion of particles on the substrate.

### BRIEF DESCRIPTION OF THE DRAWINGS

FIG. 1 is a schematic cross-sectional view illustrating a substrate processing apparatus of an embodiment according to the present invention;

FIG. 2 is a schematic cross-sectional view describing a state of a lower position where a substrate support in the substrate processing apparatus in FIG. 1 is positioned; and

FIG. 3 is a schematic cross-sectional view illustrating a part of a cover ring assembly of the substrate processing apparatus in FIG. 1.

### DETAILED DESCRIPTION OF THE INVENTION

The following describes a substrate processing apparatus of an embodiment according to the present invention with reference to the accompanied drawings. Note that, in the embodiment, the same reference numerals are given to components having substantially identical function and structure, and duplicate descriptions will be omitted.

### Embodiment 1

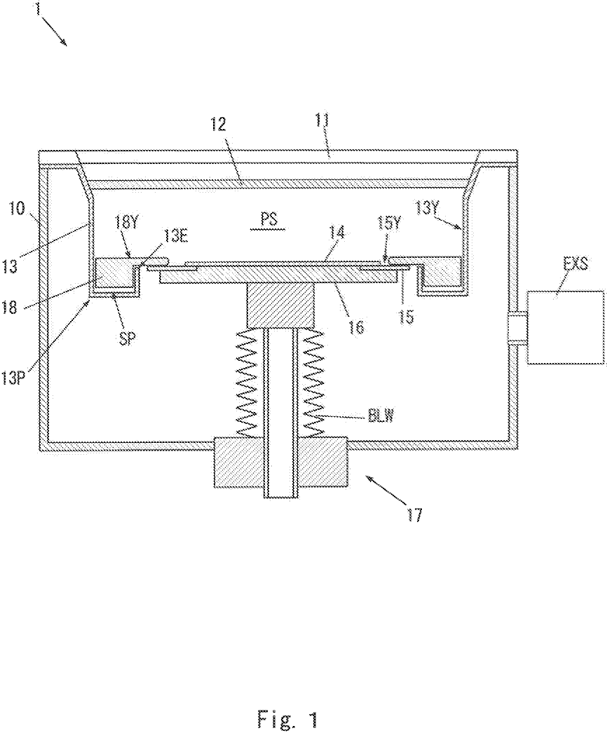

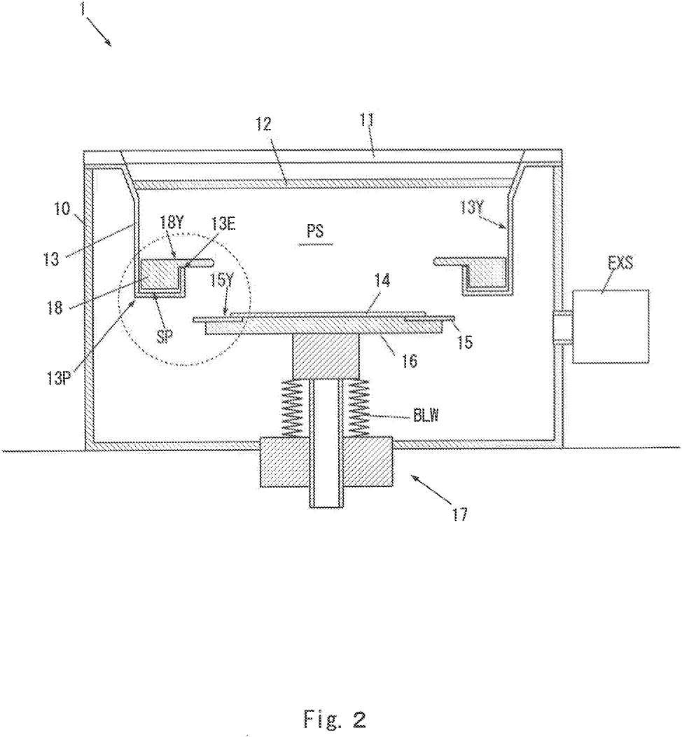

FIG. 1 illustrates a substrate processing apparatus 1 including a cover ring assembly, which is this embodiment. FIG. 2 illustrates a substrate support 16 in a state of a lower position in the substrate processing apparatus 1.

### Processing Chamber 10

In the substrate processing apparatus 1, an approximately cylindrically-shaped, hollow processing chamber 10 having a bottom portion and a sidewall portion standing upright from the bottom portion is closed by a lid body 11 to define an evacuable internal space PS.

The lid body 11 includes a target 12 that is exposed to the internal space PS of the processing chamber 10. The lid body 11 and the sidewall portion of the processing chamber 10 are hermetically sealed by a predetermined mechanism (not illustrated). A back of the target 12 in the lid body 11 can include, for example, a magnetron (not illustrated).

A cylindrically-shaped shield 13 that is insulated from the target 12 and supported by the lid body 11 or the sidewall portion of the processing chamber 10 is disposed so as to surround the internal space PS.

The target 12 exposed to the internal space PS of the processing chamber 10 supplies processing particles of a material to be deposited on a substrate 14 during a Physical Vapor Deposition (PVD) processing under a state where rare gas such as argon is supplied into the internal space PS from a gas supply source (not illustrated). The target 12 and the substrate support 16 have predetermined electric potentials biased relative each other (even DC discharge or RF discharge can be used). Plasma is formed between the substrate 14 and the target 12 by rare gas. Ions inside the plasma are accelerated and proceed toward the target 12, and a target material exits from the target 12 as the processing particles to be deposited on the substrate 14.

The cylindrically-shaped shield 13 includes a folded portion 13P having an approximately U-shaped cross section in a predetermined shape on an outside in a skirt portion of an opening at a lower end of the shield 13.

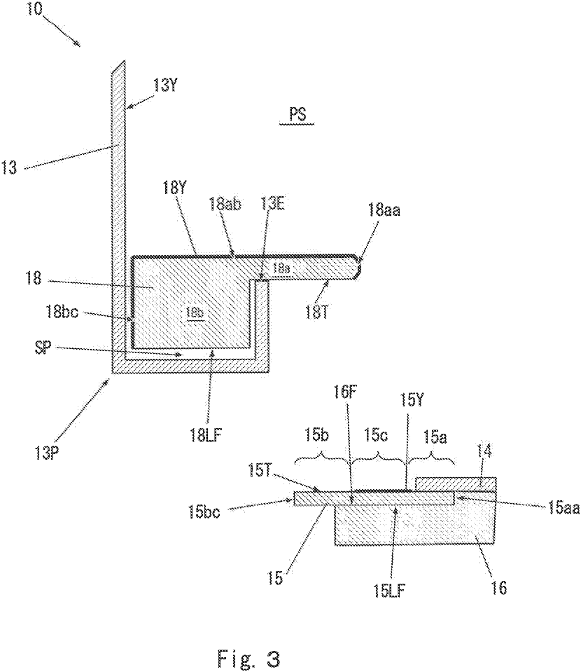

The folded portion 13P of the cylindrically-shaped shield 13 has an annular open end 13E directed upward. The open end 13E can engage with and support a cover ring 18, which will be described later, at a predetermined timing (see a case where the substrate support 16 is at a lower position in FIG. 2 and FIG. 3).

A surface on the internal space PS side of the shield 13 is covered with a thermal spraying film 13Y formed by a thermal spraying method using a metal film material such as aluminum. However, the thermal spraying film 13Y is not disposed on the annular open end 13E of the folded portion 13P of the shield 13 for suppressing delamination of the thermal spraying film.

An exhaust port disposed at the sidewall portion of the processing chamber 10 is communicated with a high vacuum pump exhaust system EXS that performs evacuation of the internal space PS and pressure control thereof.

### Substrate Support 16

The substrate support 16 that holds the substrate 14 on its upper surface together with an annular flat plate 15 is supported from below by an elevating mechanism 17 disposed at a bottom portion of the processing chamber 10. The annular flat plate 15 is fitted to a top portion of the substrate support 16, and upper surfaces of them are constituted to be flush with one another. This suppresses entering of particles and the sputtering material between the annular flat plate 15 and the substrate 14.

The substrate support 16 is joined to the bottom portion of the processing chamber 10 by the elevating mechanism 17, and the elevating mechanism 17 is configured to move the substrate support 16 between an upper position and the lower position.

The substrate support 16 is configured to include, for example, an electrostatic chuck (not illustrated) for securing the substrate 14, a temperature management system (not illustrated) of a heater or a cooling mechanism, or a combination of them. The electrostatic chuck, the temperature management system, the elevating mechanism 17, and the high vacuum pump exhaust system are controlled by respective control units (not illustrated) through wiring (not illustrated).

At the upper position of the substrate support 16, which is illustrated in FIG. 1, the annular flat plate 15 associated with the substrate support 16 engages with the cover ring 18 and lifts the cover ring 18 from the shield 13 as the substrate support 16 moves the substrate 14 upward to a processing position.

At the lower position of the substrate support 16, which is illustrated in FIG. 2, since the substrate support 16 is positioned below the shield 13, the substrate 14 can be taken out from the processing chamber 10 through a take-in/take-out port (not illustrated) disposed at the sidewall portion of the processing chamber 10. A bellows part BLW that can be freely expanded and contracted from near the bottom portion of the processing chamber 10 is disposed between the substrate support 16 and the bottom portion of the processing chamber 10 and isolates the internal space PS of the processing chamber 10 from an inside of the elevating mechanism 17.

The annular flat plate 15 is supported by the substrate support 16 and surrounds the substrate 14 to protect a peripheral area of the substrate support 16 during processing. The annular flat plate 15 is configured to engage with the cover ring 18 as the substrate support 16 is raised such that the cover ring 18 is lifted from the shield 13 (see FIG. 1).

### Cover Ring 18

FIG. 3 is a partially enlarged cross-sectional view within a dashed line circle indicated in FIG. 2 and illustrates a portion including the substrate support 16, the annular flat plate 15, and the cover ring 18. The cover ring 18 is constituted of an inner ring portion 18a extending radially inward and an outer pipe portion 18b extending toward the lower direction from the inner ring portion 18a.

A lower portion surface 18LF (a lower surface of the inner ring portion 18a and a lower surface and an inner surface of the outer pipe portion 18b) of the cover ring 18 includes an abutting surface 18T (a base material is exposed) of a part of the lower surface of the inner ring portion 18a supported by an outer peripheral upper surface 15b of the annular flat plate 15. The cover ring 18 can be manufactured from a ceramic material, for example, quartz, aluminum oxide, or other suitable insulating materials.

A cover side thermal spraying film 18Y is disposed on an upper surface of the cover ring 18. The cover side thermal spraying film 18Y covers over from a lower edge of an inner peripheral side surface 18aa of the inner ring portion 18a to an upper surface 18ab of the inner ring portion 18a and a lower edge of an outer peripheral side surface 18bc of the outer pipe portion 18b. That is, in the cover ring 18, the cover side thermal spraying film 18Y is continuously formed on the inner peripheral side surface 18aa of the inner ring portion 18a, the upper surface 18ab of the inner ring portion 18a, and the outer peripheral side surface 18bc of the outer pipe portion 18b.

On the upper surface of the cover ring 18, the cover side thermal spraying film 18Y is formed by the thermal spraying method using a metal film material, such as aluminum, that is selected for the purpose of improving adhesion degree of the sputtering material to the cover ring 18.

In the cover ring 18, an area from the lower edge portion of the outer peripheral side surface 18bc of the outer pipe portion 18b up to the abutting surface 18T of the lower surface of the inner ring portion 18a forms a gap part SP with a concave surface of the folded portion 13P having the approximately U-shaped cross-sectional surface of the shield 13. That is, the outer pipe portion 18b of the cover ring 18 and the folded portion 13P of the shield 13 have dimensions such that when the outer pipe portion 18b engages with the folded portion 13P in a spaced relation and loosely fitted, a labyrinth-like gap part is defined therebetween.

### Annular Flat Plate 15

A flat plate side thermal spraying film 15Y is formed on a part of the upper surface of the annular flat plate 15, that is, an intermediate upper surface 15c between the outer peripheral upper surface 15b and an inner peripheral upper surface 15a. Since the thermal spraying film, which has been thermally sprayed, and/or the sputtering material adhering thereon are conductive in some cases, by the flat plate side thermal spraying film 15Y on the annular flat plate 15 being selectively formed in an area inside the intermediate upper surface 15c sufficiently separated from the substrate 14, even after a large amount of sputtering material adheres to the cover side thermal spraying film 18Y, short circuit can be suppressed.

An abutting surface 15T (the base material is exposed) abutting on the abutting surface 18T disposed on the lower surface of the inner ring portion 18a of the cover ring 18 is disposed on a part of the upper surface of the annular flat plate 15, that is, the outer peripheral upper surface 15b. The base materials of the abutting surface 15T on the upper surface of the annular flat plate 15 and the abutting surface 18T inside the lower portion surface 18LF of the cover ring 18 are directly brought into contact with one another.

Similarly to the cover ring 18, the annular flat plate 15 may be manufactured from a ceramic material, for example, quartz, aluminum oxide, or other suitable insulating materials. For example, when the annular flat plate 15 is formed of a material identical to a dielectric material of the electrostatic chuck of the substrate support 16, as a modification, a substrate holding assembly where the annular flat plate 15 and the substrate support 16 are combined can be manufactured.

An inner peripheral side surface 15aa of the annular flat plate 15 defines an innermost diameter of the annular flat plate 15, and an outer peripheral side surface 15bc of the annular flat plate 15 defines an outermost diameter of the annular flat plate 15.

Any thermal spraying film is not formed on a lower surface of the inner peripheral side surface 15aa side and the inner peripheral side surface 15aa of the annular flat plate 15.

The annular flat plate 15 is fitted to a top portion of the substrate support 16 such that a depth of a stepped portion of a flange 16F of the substrate support 16 is equal to a thickness of the annular flat plate 15, and the upper surfaces of the annular flat plate 15 and the substrate support 16 are configured to be flush with one another. A lower portion surface 15LF of the annular flat plate 15 is closely fitted and supported on the flange 16F of the substrate support 16.

The upper surface of the annular flat plate 15, that is, the outer peripheral upper surface 15b, the inner peripheral upper surface 15a, and the intermediate upper surface 15c are connected as a common plane. The flat plate side thermal spraying film 15Y is formed on the intermediate upper surface 15c.

When the annular flat plate 15 is fitted into the stepped portion of the flange 16F of the substrate support 16, an outer diameter of the area of the intermediate upper surface 15c is larger than an outer diameter of the substrate 14 and smaller than an inner diameter of the cover ring 18 (the inner ring portion 18a).

The annular flat plate 15 includes the plasma resistant flat plate side thermal spraying film 15Y that can cause the sputtering material to adhere. In this embodiment, the flat plate side thermal spraying film 15Y may be the same as the cover side thermal spraying film 18Y.

The reason why the position of the flat plate side thermal spraying film 15Y is limited to the intermediate upper surface 15c of the annular flat plate 15 is to allows the outer peripheral upper surface 15b (both abutting surfaces) supporting the lower portion surface 18LF (the abutting surface) of the cover ring 18 thereon to suppress the delamination of the thermal spraying film between the annular flat plate 15 and the cover ring 18 and to suppress short circuit between the annular flat plate 15 and the cover ring 18.

While the above-described embodiment includes a sputtering apparatus, the application of the present invention is not limited to this, and it is possible to apply the present invention to all the vacuum film formation apparatuses equipped with a cover ring. Specifically, it is possible to apply the present invention to other physical vapor deposition apparatuses using an electron beam or the like, a chemical vapor deposition (CVD) apparatus, an atomic layer deposition (ALD) apparatus, and the like.

What is claimed is:

1. A substrate processing apparatus comprising:
a processing chamber;
a substrate support that is disposed in the processing chamber and movable in a vertical direction, the substrate support having an upper surface with a substrate holding surface, the substrate holding surface having a substrate holding area and an annular area, the substrate holding area being configured to contact and hold a substrate, the annular area being disposed in an annular shape in a peripheral edge of the substrate holding area; and
a cover ring having an annular shape and a lower surface with an inner edge portion, the cover ring having an annular abutting surface at the inner edge portion of the lower surface, the cover ring being disposed in the processing chamber, the annular abutting surface abutting on the annular area when the substrate support moves upward in the vertical direction, wherein
thermal spraying films are formed on surfaces of the substrate holding surface and the cover ring, and the abutting surfaces of the substrate support and the cover ring against one another are exposed from the thermal spraying films.

2. A substrate holding assembly comprising:
a substrate support that is housed in an internal space formed by a processing chamber of a substrate processing apparatus and movable in a vertical direction, the substrate support having an upper surface with a substrate holding surface, the substrate holding surface having a substrate holding area and an annular area, the substrate holding area being configured to contact and hold a substrate, the annular area being disposed in an annular shape of a peripheral edge of the substrate holding area; and
a cover ring having an annular shape and a lower surface with an inner edge portion, the cover ring having an annular abutting surface at the inner edge portion of the lower surface, the annular abutting surface abutting on the annular area when the substrate support moves upward in the vertical direction, wherein
thermal spraying films are formed on surfaces of the substrate holding surface and the cover ring, and the abutting surfaces of the substrate support and the cover ring against one another are exposed from the thermal spraying films.

3. A cover ring assembly for a substrate processing apparatus that exposes a substrate to processing particles in an internal space to process the substrate, the cover ring assembly comprising:
an annular flat plate having an inner peripheral upper surface and an outer peripheral upper surface, the inner peripheral upper surface being in contact with an outer peripheral lower surface terminating at an outer surface of the substrate, the outer peripheral upper surface being around the inner peripheral upper surface; and
a cover ring having an annular shape and a lower portion surface, the lower portion surface having an abutting surface being in contact with the outer peripheral upper surface of the annular flat plate, wherein
a thermal spraying film covering a surface exposed to the processing particles is disposed to the cover ring except for the abutting surface.

4. The cover ring assembly according to claim 3, wherein
a thermal spraying film is disposed to cover a surface of the annular flat plate, the surface is exposed to the processing particles except for the outer peripheral upper surface in contact with the abutting surface of the cover ring.
